(19) United States
(12) Patent Application Publication
(10) Pub. No.: US 2025/0053709 A1
(43) Pub. Date: Feb. 13, 2025

(54) Inverter-Based Resource or Plant Modeling

(71) Applicant: Quanta Technology, LLC, Raleigh, NC (US)

(72) Inventors: Zheyuan Cheng, Apex, NC (US); Juergen Holbach, Raleigh, NC (US); Srinidhi Narayanan, Morrisville, NC (US); David G. Hart, Raleigh, NC (US)

(21) Appl. No.: 18/434,231

(22) Filed: Feb. 6, 2024

Related U.S. Application Data
(60) Provisional application No. 63/518,917, filed on Aug. 11, 2023.

(51) Int. Cl. G06F 30/27; G06F 8/30

(52) U.S. Cl. CPC G06F 30/27; G06F 8/315

(57) ABSTRACT

A method is disclosed for exporting a black-box model of an inverter-based resource or plant from a first software platform for use by a second software platform. The method comprises simulating, using the first software platform, instantaneous time-domain responses of the inverter-based resource or plant to respective conditions defined by a script, according to the black-box model. The method may further comprise generating training data from the instantaneous time-domain responses and the respective conditions. The method may further comprise, with the training data, training a machine learning model to model the inverter-based resource or plant, wherein the trained machine learning model is transparent as to its inner workings. The method may further comprise generating software code that represents the trained machine learning model in terms of software code usable for defining a custom model of the inverter-based resource or plant in the second software platform.

### TECHNICAL FIELD

The present application relates generally to inverter-based resources or plants, and relates more particularly to modeling such inverter-based resources or plants in a data-driven way.

### BACKGROUND

Throughout history, the primary sources of electricity has been a combination of hydropower, nuclear, coal, and natural gas. These traditional “synchronous” generation resources, capable of naturally producing alternating current (AC) power, have played a crucial role in transmitting electricity over long distances and establishing a reliable grid operation. However, with the increasing integration of renewable energy sources into the generation mix, the role of synchronous generation resources is diminishing. In their place, inverter-based resources (IBRs) like wind, solar photovoltaic, and battery storage are gaining prominence. Unlike conventional synchronous generation resources, IBRs utilize inverters to convert their direct current (DC) electrical output into AC power before feeding it into the grid.

An inverter is a power electronic device designed to convert DC power into AC power, i.e., effectively inverting a rectifier's operation. The integration of IBRs into the electric system brings about new possibilities but also introduces operational challenges and potential reliability risks. Unlike synchronous generation, IBRs may exhibit different behavior in response to disturbances on the electric grid. While synchronous generation resources automatically support reliability by continuing to operate seamlessly during disturbances, IBRs need to be programmed for this “ride through” capability. Failure to do so may result in a reduction or cessation of power supply during a disturbance. With the increasing use of solar, wind, and other generation technologies utilizing inverters, it is crucial to consider the unique characteristics of these technologies to ensure the reliable operation of the electric grid.

However, challenges exist in performing studies of power systems that include IBRs. Manufacturers of IBRs heretofore only provide software-specific black-box models appropriate for offline studies, e.g., black-box models designed to run in PSCAD®. Indeed, black-box IBR models conceal the key, if not all, parameters or configurations of the IBR electrical, mechanical, and control components. Because of this lack of transparency to the inner workings of black-box IBR models, end users are heretofore unable to export or re-create the manufacturer-provided software-specific black-box IBR model to other software platforms, for performing power system studies without any support from the IBR manufacturer. As a result, end users don't have available models for Electromagnetic Transient (EMT) real-time simulation studies, e.g., with e.g., Real-Time Digital Simulation (RTDS)®, Nor do users have available models for offline simulation studies using unsupported but commonly used EMT simulation software, e.g., MATLAB/Simulink®.

### SUMMARY

Some embodiments herein export a black-box model of an inverter-based resource or plant from a first software platform for use by a second software platform. Some embodiments in this regard train a machine learning model to model the inverter-based resource or plant, e.g., with a long short-term memory (LSTM) network. This machine learning model is trained using training data generated from simulations performed by the first software platform with the black-box model. With the trained machine learning model being transparent as to its inner workings, software code is generated to represent the trained machine learning mode, e.g., C or C++ code. This software code is advantageously usable for defining a custom model of the inverter-based resource or plant in the second software platform.

Some embodiments accordingly prove effective for exporting a black-box model of an inverter-based resource or plant from a non-real-time Electromagnetic Transient (EMT) simulation platform, e.g., PSCAD®. The exported model may for example be used for defining a custom model of the inventor-based resource or plant in another non-real-time EMT simulation platform like MATLAB/Simulink®, or even in a real-time EMT simulation platform like Real-Time Digital Simulation (RTDS)®. As such, some embodiments advantageously expand the usability of manufacturer-provided black-box models, e.g., to be software platform-agnostic. In doing so, some embodiments herein advantageously enable more comprehensive and effective studies of power systems that include inverter-based resources or plants.

More particularly, embodiments herein include a method for exporting a black-box model of an inverter-based resource or plant from a first software platform for use by a second software platform. The method comprises simulating, using the first software platform, instantaneous time-domain responses of the inverter-based resource or plant to respective conditions defined by a script, according to the black-box model of the inverter-based resource or plant. The method also comprises generating training data from the instantaneous time-domain responses and the respective conditions. The method also comprises, with the training data, training a machine learning model to model the inverter-based resource or plant, wherein the trained machine learning model is transparent as to its inner workings. The method also comprises generating software code that represents the trained machine learning model in terms of software code that is usable for defining a custom model of the inverter-based resource or plant in the second software platform.

In some embodiments, the black-box model is specific to the first software platform, and the generated software code is not specific to the first software platform.

In some embodiments, the first software platform is a first non-real-time Electromagnetic Transient (EMT) simulation platform, and the second software platform is a second non-real-time EMT simulation platform or a real-time EMT simulation platform.

In some embodiments, the machine learning model is a deep learning model.

In some embodiments, the machine learning model is a long short-term memory (LSTM) network.

In some embodiments, the software code is C or C++ code.

In some embodiments, the script is a Python script.

In some embodiments, the method further comprises defining a custom model of the inverter-based resource or plant in the second software platform by importing the generated software code into the second software platform. In some embodiments, the method further comprises performing a power system study of the inverter-based resource or plant on the second software platform, with the inverter-based resource or plant modeled with the custom model in the second software platform.

In some embodiments, generating the training data further comprises generating the training data also from field measurements of instantaneous time-domain responses of the inverter-based resource or plant to one or more of the conditions.

Other embodiments herein include a non-transitory computer-readable medium on which is stored instructions that, when executed by one or more processors of computing equipment, cause the computing equipment to export a black-box model of an inverter-based resource or plant from a first software platform for use by a second software platform. The instructions are configured to cause the computing equipment to simulate, using the first software platform, instantaneous time-domain responses of the inverter-based resource or plant to respective conditions defined by a script, according to the black-box model of the inverter-based resource or plant. The instructions are configured to also cause the computing equipment to generate training data from the instantaneous time-domain responses and the respective conditions. The instructions are configured to also cause the computing equipment to, with the training data, train a machine learning model to model the inverter-based resource or plant, wherein the trained machine learning model is transparent as to its inner workings. The instructions are configured to also cause the computing equipment to generate software code that represents the trained machine learning model in terms of software code that is usable for defining a custom model of the inverter-based resource or plant in the second software platform.

In some embodiments, the black-box model is specific to the first software platform, and the generated software code is not specific to the first software platform.

In some embodiments, the first software platform is a first non-real-time Electromagnetic Transient (EMT) simulation platform, and the second software platform is a second non-real-time EMT simulation platform or a real-time EMT software platform.

In some embodiments, the machine learning model is a deep learning model.

In some embodiments, the machine learning model is a long short-term memory (LSTM) network.

In some embodiments, the software code is C or C++ code.

In some embodiments, the script is a Python script.

In some embodiments, the instructions further configured to cause the computing equipment to define a custom model of the inverter-based resource or plant in the second software platform by importing the generated software code into the second software platform. In some embodiments, the instructions further configured to cause the computing equipment to perform a power system study of the inverter-based resource or plant on the second software platform, with the inverter-based resource or plant modeled with the custom model in the second software platform.

In some embodiments, the instructions configured to cause the computing equipment to generate the training data also from field measurements of instantaneous time-domain responses of the inverter-based resource or plant to one or more of the conditions.

Other embodiments herein include computing equipment for exporting a black-box model of an inverter-based resource or plant from a first software platform for use by a second software platform. The computing equipment comprises processing circuitry configured to simulate, using the first software platform, instantaneous time-domain responses of the inverter-based resource or plant to respective conditions defined by a script, according to the black-box model of the inverter-based resource or plant. The computing equipment comprises processing circuitry also configured to generate training data from the instantaneous time-domain responses and the respective conditions. The computing equipment comprises processing circuitry also configured to, with the training data, train a machine learning model to model the inverter-based resource or plant, wherein the trained machine learning model is transparent as to its inner workings. The computing equipment comprises processing circuitry also configured to generate software code that represents the trained machine learning model in terms of software code that is usable for defining a custom model of the inverter-based resource or plant in the second software platform.

### BRIEF DESCRIPTION OF THE DRAWINGS

FIG. 1 is a block diagram of a method and system for exporting a black-box model of an inverter-based resource or plant from one software platform for use in another software platform according to some embodiments.

FIG. 2 is a block diagram of a method and system for exporting a black-box model of an inverter-based resource or plant from one software platform for use in another software platform according to other embodiments.

FIG. 3 is a block diagram of the architecture of a long short-term memory (LSTM) network according to some embodiments.

FIG. 4 is a table of LSTM network parameters according to some embodiments.

FIG. 5 is a block diagram of the structure of the LSTM network based IBR model in one example.

FIG. 6 is a line graph showing a comparison between the IBR manufacturer black box model response and a data-driven model response according to some embodiments.

FIG. 7 is a line graph showing a comparison between the IBR manufacturer black box model response and a data-driven model response according to other embodiments.

FIG. 8 is a logic flow diagram of a method for exporting a black-box model of an inverter-based resource or plant from one software platform for use in another software platform according to some embodiments.

FIG. 9 is a block diagram of computing equipment for exporting a black-box model of an inverter-based resource or plant from one software platform for use in another software platform according to some embodiments.

### DETAILED DESCRIPTION

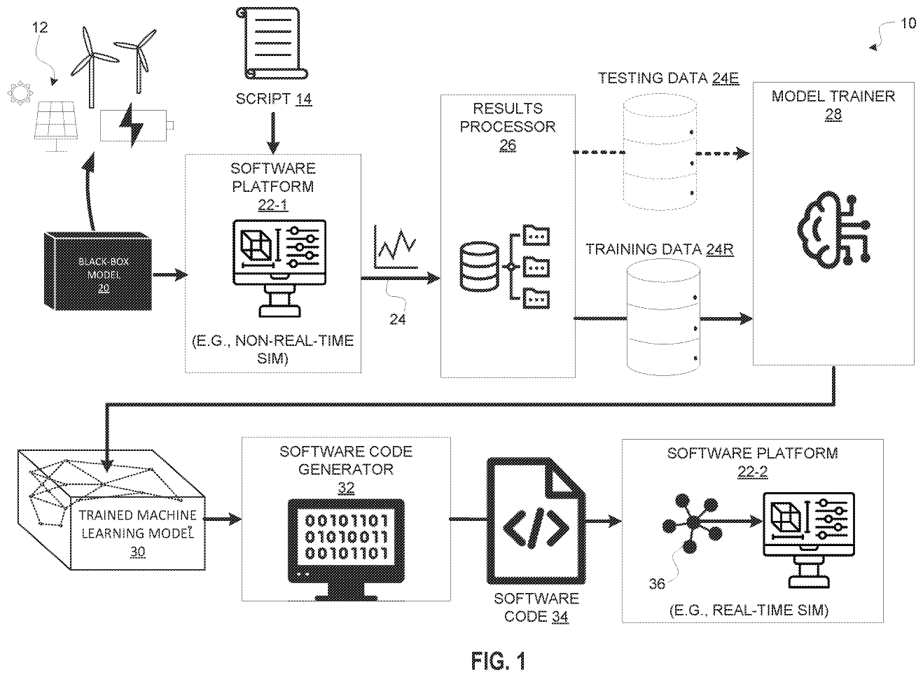

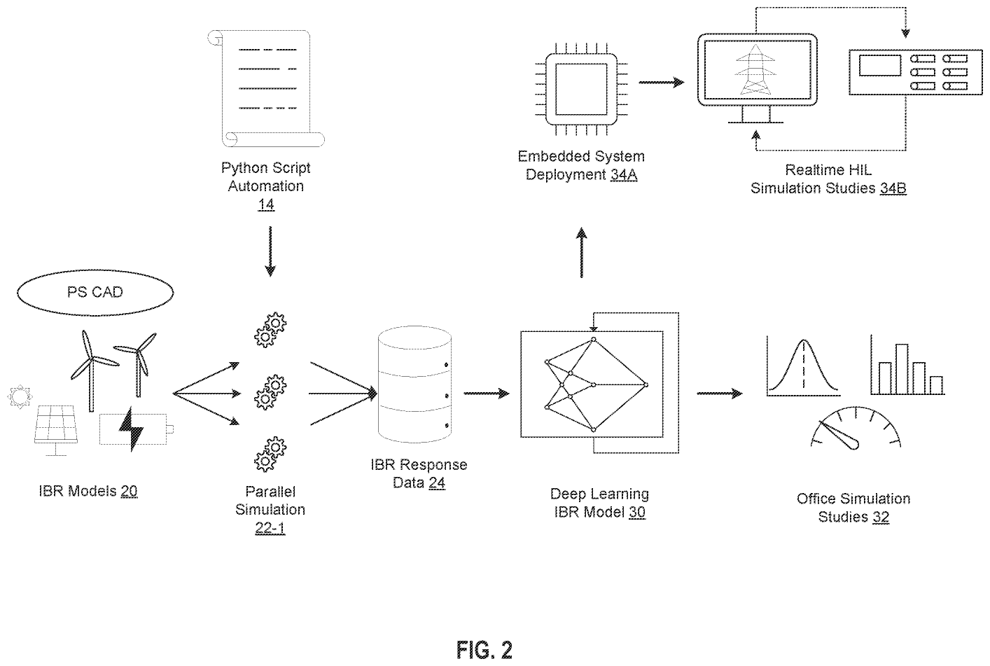

FIG. 1 shows an inverter-based resource (IBR) or plant 12. The inverter-based resource or plant 12 may be a single inverter, an IBR plant, or a cluster of multiple IBR plants. The inverter-based resource or plant 12 may generate power from wind turbines, solar photovoltaic (PV) cells, battery storage systems, or other renewable energy sources. The inverter-based resource or plant 12 may be connectable to a bulk power system (BPS) (not shown).

A black-box model 20 models the inverter-based resource or plant 12. The black-box nature of the model 20 means that the model 20 lacks both transparency and interpretability. Because the black-box model 20 lacks transparency, the inner workings of the black-box model 20 are concealed. Accordingly, although the input data set and the output produced by the black-box model 20 from that input data set are observable, how the black-box model 20 determines the output from the input data set is not revealed and is therefore not observable. The black-box model 20 may for instance be opaque as to how the black-box model 20 processes its input, which variables the black-box model 20 gives weight to, and/or how the black-box model 20 generates its predictions. Such concealment may be intentional in order to simplify the model 20 for the user and/or to safeguard proprietary design of the inverter-based resource or plant 12. In fact, in some embodiments, the black-box model 20 is provided by a manufacturer of the inverter-based resource or plant 12.

The black-box nature of the model 20 threatens to limit its usability, though. For example, in some embodiments, the black-box model 20 is specific to software platform 22-1, e.g., a non-real-time Electromagnetic Transient (EMT) simulation platform such as PSCAD®. The black-box model 20 in this case may only be imported by that software platform 22-1, limiting the types of studies that can be performed using the black-box model 20 to those that can be performed by that software platform 22-1.

Some embodiments herein provide a method and a system 10 for exporting the black-box model 20 from software platform 22-1 for use by another software platform 22-2, e.g., a different non-real-time EMT simulation platform like MATLAB/Simulink® or a real-time EMT simulation platform such as Real-Time Digital Simulation (RTDS)®.

As shown in FIG. 1 in this regard, software-platform 22-1 is used to simulate instantaneous time-domain responses 24 of the inverter-based resource or plant 12 to respective conditions, e.g., disturbances, events, or changes in operating conditions such as fault conditions, low voltage ride through conditions, etc. These conditions may be defined by a script 14 (e.g., a Python script) which governs and/or controls the simulations. The instantaneous time-domain responses 24 may include variables such as voltage, current, and/or power, represented as functions of time, e.g., on a transient basis and/or steady state basis. With the inverter-based resource or plant 20 represented by the black-box model 20 in the simulations, these responses 24 resulting from the simulations provide insights into how the inverter-based resource or plant 12 reacts to the different conditions.

The resulting instantaneous time-domain responses 24 are then processed, e.g., by results processor 26, in order to tailor or condition the simulation results for further use. Such processing involves generating training data 24R from the instantaneous time-domain responses 24 and the respective conditions. Processing may also involve generating testing data 24E from the instantaneous time-domain responses 24 and the respective conditions, usable for model validation. For example, in some embodiments, one subset of instantaneous time-domain responses 24 is selected (e.g., randomly) to serve as the training data 24R and another subset of instantaneous time-domain responses 24 is selected to serve as the testing data 24E, e.g., 70% for training and 30% for testing. In some embodiments, the training data 24R is generated also from field measurements of instantaneous time-domain responses of the inverter-based resource or plant 12 to one or more of the conditions, e.g., to supplement the training data 24R with real-world observations.

A model trainer 28 (e.g., MATLAB) uses this training data 24R to train a machine learning model 30 to model the inverter-based resource or plant 12. The model trainer 28 may also use the testing data 24E, if available, for validating the trained machine learning model 30 as an accurate representation or approximation of the black-box model 20, e.g., by comparing responses from the trained machine learning model 30 to corresponding responses from the black-box model 20. The trained machine learning model 30 that results from this training may thereby represent the inverter-based resource or plant 12 substantially similarly to the black-box model 20 in terms of input and output values. The trained machine learning model 30 may not be any more inherently explainable than the black-box model 20, e.g., the inner workings of the trained machine learning model 30 may not reveal any electrical meaning for explaining the design of the inverter-based resource or plant 12. Notably, though, the trained machine learning model 30 is transparent as to its inner workings. That is, unlike the black-box model 20, the inner workings of the trained machine learning model 30 are not concealed and are therefore observable.

Consider, for example, embodiments where the trained machine learning model 30 is a deep learning model such as a long short-term memory (LSTM) network. An LSTM is a specific kind of recurrent neural network (RNN) designed to overcome the vanishing gradient problem, which can occur in traditional RNNs. The architecture of an LSTM includes memory cells and gating mechanisms that allow it to capture and remember long-term dependencies in data. In such embodiments where the trained machine learning model 30 is an LSTM network, the trained machine learning model 30 may model the inverter-based resource or plant 12 in terms of parameters that describe (1) a number of layers of the LSTM network, (2) neural network layer types, e.g., input layer, fully connected layer, etc.; (3) a number of hidden units of the LSTM network; (4) input/output size; and (5) activation functions.

Regardless of the particular parameters, though, some embodiments herein exploit the observability of trained machine learning model's inner workings. As shown in FIG. 1 in this regard, a software code generator 32 (e.g., MATLAB) generates software code 34 that represents the trained machine learning model 30. Indeed, the trained machine learning model 30 may be represented with parameters and equations that can be captured in software code 34, e.g., by quantizing the weights, biases, and activations of layers and then generating the software code 34 from the quantized network. The software code 34 may for instance be written in C, C++, CUDA (Computer Unified Device Architecture), HDL (Hardware Descriptive Language), or any programming language that is importable into for the target software platform 22-2. As such, while the black-box model 20 may have been specific to software platform 22-1, the generated software code 34 may not be specific to software platform 22-1.

To this point, FIG. 1 shows that the software code is usable for defining a custom model 36 of the inverter-based resource or plant 12 in software platform 22-2. Some embodiments herein therefore define this custom model 36 of the inverter-based resource or plant 12 in software platform 22-2 by importing the generated software code 34 into software platform 22-2. The custom model 36 may be custom in the sense that the model 36 is not predefined by software platform 22-2 as a standard or built-in option, but rather is custom defined by a user of the software platform 22-2. A power system study of the inverter-based resource or plant 12 may then advantageously be performed on software platform 22-2, with the inverter-based resource or plant 12 modeled with the custom model 36 in software platform 22-2.

Accordingly, in embodiments where software platform 22-2 is a different non-real-time EMT simulation platform like MATLAB/Simulink®, or a real-time EMT simulation platform like Real-Time Digital Simulation (RTDS)®, some embodiments advantageously expand the usability of the black-box model 20, e.g., to be software platform-agnostic. In doing so, some embodiments herein advantageously enable more comprehensive and effective studies of power systems that include inverter-based resources or plants.

Some embodiments may for example enable real-time EMT simulation of the inverter-based resource or plant 12, e.g., so as to provide the ability to connect external hardware and update inputs and outputs in real time to the simulated environment, and then test it in a closed loop. This closed loop test allows observability of the response of protection or control devices to an imposed signal, but also allows interfacing external devices to respond back into the simulated network. This is also known as HIL (Hardware-in-the-loop) testing.

Some embodiments herein therefore generally provide a non-invasive way for end users to create an accurate IBR data-driven model for real-time and offline simulations on commonly used EMT simulation software.

Some embodiments in this regard use machine learning technologies to intelligently extract and classify power system events from synchrophasor data, e.g., a large amount of synchrophasor data. Therefore, some embodiments help engineers/operators filter out trivial events and direct their attention to remarkable events that may be unpredictable and could have potentially severe consequences.

Note that some embodiments leverage a parallel computing architecture (e.g., for software platform 22-1) that enables an ultra-fast event detection speed and provides high scalability for synchrophasor databases of various sizes. In addition, some embodiments include specialized signal processing module(s) that are integrated so that the detection performance remains high, even in the presence of poor data quality.

Generally, then, some embodiments aim to create an accurate data-driven model of an inverter-based resource (IBR) or an aggregated model of an IBR plant. Note here that the trained machine learning model 30 may also be informally referred to as a data-driven model, because it is the data (not the manufacturer) that drives the model 30.

One motivation for doing so is that IBR is known for its drastically different dynamic behaviors compared with conventional generation sources, and individual IBR behaviors can greatly vary due to different IBR manufacturers' implementations. Therefore, accurate time-domain ElectroMagnetic Transients (EMT) models of IBR are highly desirable for power system studies. However, at the time being, IBR manufacturers only provide software-specific black-box models for offline studies, e.g., black-box models designed to run in PSCAD®. Black-box IBR models typically conceal the key, if not all, parameters/configurations of the IBR electrical, mechanical, and control components. Thus, end users are heretofore unable to export or re-create the manufacturer-provided software-specific black-box to other software platforms to perform other necessary power system studies without any IBR manufacturer's support. At the time being, end users don't have available models for EMT real-time simulation studies or offline simulation studies using unsupported but commonly used EMT simulation software, e.g., MATLAB/Simulink®.

Certain embodiments may accordingly provide one or more of the following technical advantage(s). (1) The data-driven model in some embodiments herein is highly accurate. End users can create an accurate data representation of the IBR black-box model without any support from the IBR manufacturer, thus avoiding the limitation of supported simulation software by the IBR manufacturer. (2) The deep learning IBR model is software platform-agnostic and can be integrated with many commonly used simulation software. (3) the deep learning IBR model can be deployed in real-time simulation systems, e.g., RTDS®, Opal-RT®, Typhoon®, Speedgoat®, etc., for real-time hardware-in-the-loop simulation studies.

Consider a specific example of some embodiments herein. In this example, there are three components: (1) automated training and testing data generation; (2) data-driven model generation using deep learning; and (3) deep learning model C/C++ code generation for real-time and offline simulations.

FIG. 1 provides an overview of the IBR data-driven modeling workflow according to some embodiments. The first component, “automated training and testing data generation”, consists of three steps: (1) IBR manufacturer PSCAD® black-box models preparation and Python script automation development. (2) parallel simulation for IBR response data generation, and (3) IBR response database creation. There are two main benefits of this component: data generation efficiency; and data authenticity.

With regard to data generation efficiency: To train a good deep learning model, one needs to create a comprehensive IBR response database that covers various IBR behaviors under different conditions, e.g., close-in faults, external disturbances, low/high voltage ride through, etc. However, the simulation of IBR manufacturer black-box models 30 in PSCAD® is typically extremely time-consuming. It could take days, if not weeks, to simulate all the possible conditions, and it will heretofore need human interventions to configure each IBR working condition. Some embodiments herein take advantage of the Python scripting feature supported by PSCAD®, which allows the user to predefine all possible IBR working conditions and automate the simulation. Additionally, the some embodiments take advantage of the parallel computing feature supported by PSCAD® that allows multiple cases to simulate simultaneously on a multi-core CPU. Depending on the hardware CPU configuration, the parallel simulation can speed up the overall simulation by at least 800%.

With regard to data authenticity: the training and testing data 24R, 24E are generated by IBR manufacturer-provided PSCAD® black-box models. In practice, this is considered the most authentic source of data, as these black-box models are typically validated by IBR manufacturers. Note that field-measured IBR data can also be included as the training and testing data 24R, 24E herein. Due to security and physical limitations, certain IBR responses cannot be systematically measured in the field. For example, it is impractical to perform short-circuit experiments on energized transmission lines adjacent to an IBR facility. The short-circuit experiments will likely create hazardous arc flash and cause irreversible device damage. In the simulation, by contrast, one can simulate hundreds of short-circuit cases with different configurations. Therefore, for applications related to short-circuit behaviors, some embodiments include field-measured data as a supplement to simulated data.

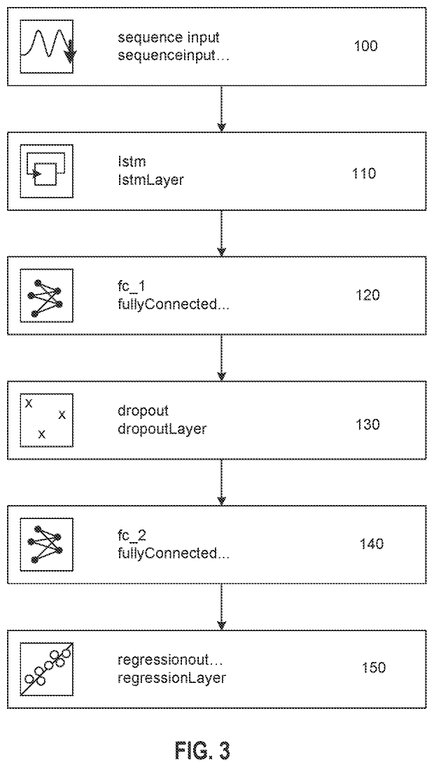

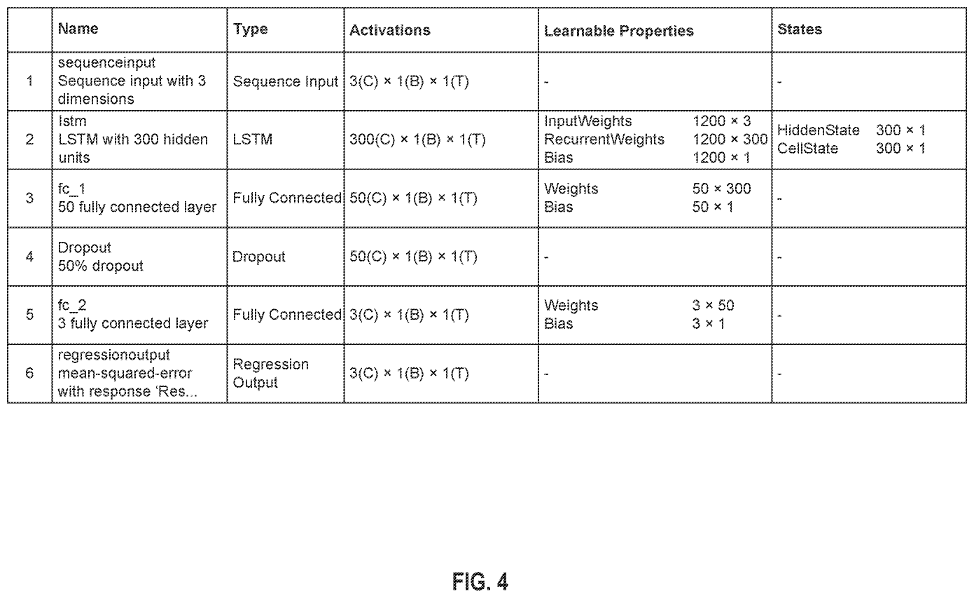

Consider now the second component, i.e., “data-driven model generation using deep learning”. The data-driven model used herein is called long short-term memory (LSTM) networks, which is a deep learning model that is well-suited for predictions based on time series data. Inverter responses are essentially time series data; therefore, they can be predicted using LSTM networks. Some embodiments herein exploit an LSTM network with the architecture shown in FIG. 3. This LSTM network consists of 6 layers: sequence input 100, LSTM 110, fully connected #1 120, drop out 130, fully connected #2 140, and regression output layers 150. Detailed properties of the LSTM network in one example are summarized in FIG. 4. There are a total of 380,000 learnables in this LSTM network.

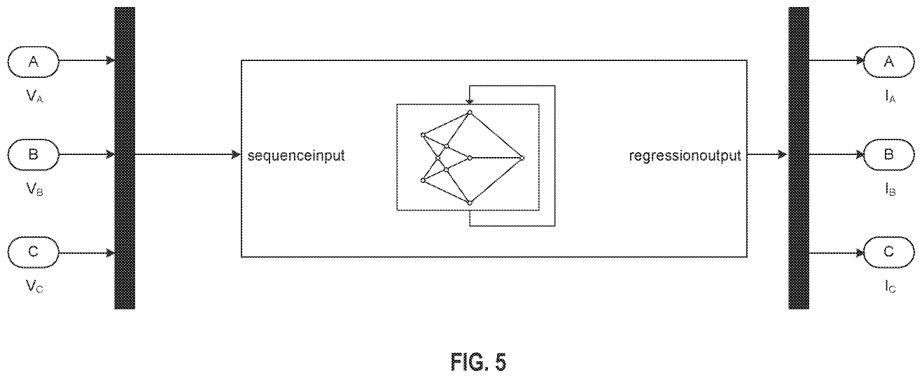

FIG. 5 presents the structure of the LSTM network based IBR model in one example. There are three inputs to the trained LSTM network: phase A voltage, phase B voltage, and phase C voltage. There are three outputs: phase A current, phase B current, and phase C current. All input/output quantities are instantaneous values measured in the time domain. There are two main benefits of this component: high modeling accuracy; and modeling flexibility.

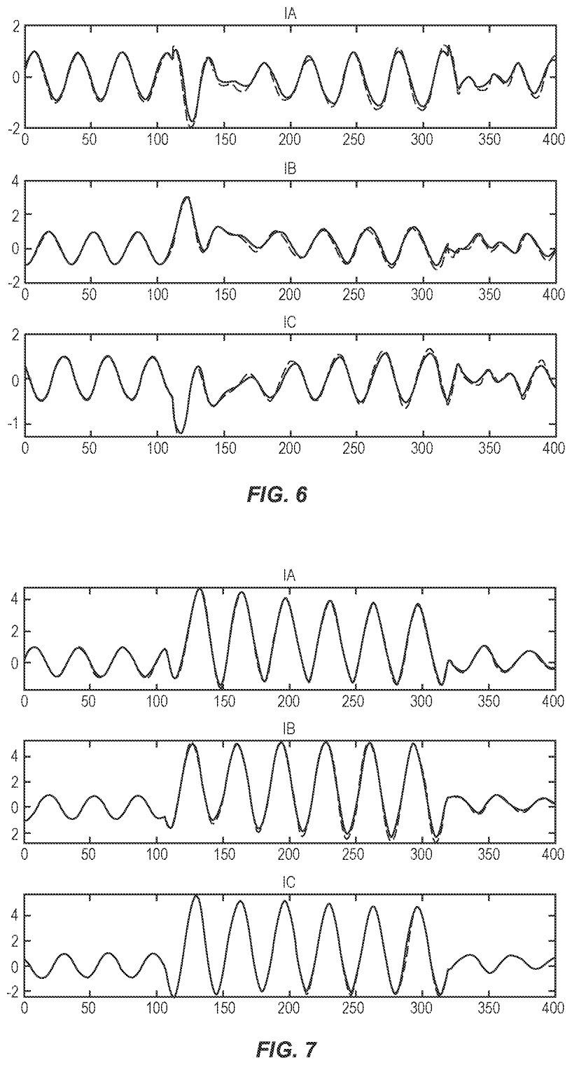

With regard to high modeling accuracy: The LSTM network based IBR model can accurately represent IBR responses with minimum error (e.g., ≤5% modeling error). FIG. 6 and FIG. 7 show two example comparisons between the IBR manufacturer black box model response (dashed) and the data-driven model response according to some embodiments (solid). One can see that the data-driven IBR model can accurately match the response during fault conditions as well as post-fault recovery responses.

With regard to modeling flexibility: The LSTM network based IBR model can be used to represent a single inverter, an IBR plant, or a cluster of IBR plants. Study engineers may have limited information about plant-level information, collector system configurations, plant controller logic, the presence of reactive compensation devices, etc. In this case, the IBR model can be used to create an aggregated IBR model to represent an IBR plant or a cluster of IBR plants.

The third component is “deep learning model C/C++ code generation for real-time and offline simulations.” The trained LSTM network IBR model supports C/C++ code generation. The generated C/C++ code can be imported to other real-time and offline simulation software to perform various types of studies.

There are two main benefits of this component: (1) support for both real-time and non-real-time simulations; and (2) software platform agnostic.

With regard to support for both real-time and non-real-time simulations: For example, the generated C/C++ code can be deployed on embedded systems to perform real-time hardware-in-the-loop simulations. Or it can be imported to offline simulation software to perform planning and reliability studies.

With regard to software platform agnostic: commonly used time domain simulation software typically allows users to create customized models using C/C++ source code. The generated C/C++ code of the LSTM network model can be included in many different simulation software.

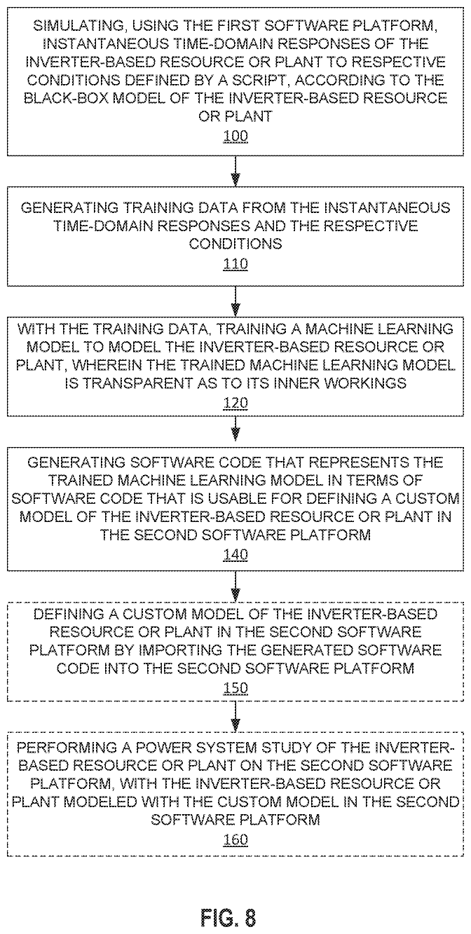

In view of the modifications and variations herein, FIG. 8 depicts a method for exporting a black-box model 20 of an inverter-based resource or plant 12 from a first software platform 22-1 for use by a second software platform 22-2 in accordance with particular embodiments. The method includes simulating, using the first software platform 22-1, instantaneous time-domain responses 24 of the inverter-based resource or plant 12 to respective conditions defined by a script 14, according to the black-box model 20 of the inverter-based resource or plant 12 (Block 100). The method also comprises generating training data 24R from the instantaneous time-domain responses 24 and the respective conditions (Block 110). The method also comprises, with the training data 24R, training a machine learning model 30 to model the inverter-based resource or plant 12 (Block 120). In some embodiments, the trained machine learning model 30 is transparent as to its inner workings. The method also comprises generating software code 34 that represents the trained machine learning model 30 in terms of software code 34 that is usable for defining a custom model 36 of the inverter-based resource or plant 12 in the second software platform 22-2 (Block 140).

In some embodiments, the black-box model 20 is specific to the first software platform 22-1, and the generated software code 34 is not specific to the first software platform 22-1. In some embodiments, the first software platform 22-1 is a first non-real-time Electromagnetic Transient (EMT) simulation platform, and the second software platform 22-2 is a second non-real-time EMT simulation platform or a real-time EMT simulation platform.

In some embodiments, the machine learning model 30 is a deep learning model.

In some embodiments, the machine learning model 30 is a long short-term memory (LSTM) network.

In some embodiments, the software code 34 is C or C++ code.

In some embodiments, the script 14 is a Python script.

In some embodiments, the method further comprises defining a custom model 36 of the inverter-based resource or plant 12 in the second software platform 22-2 by importing the generated software code 34 into the second software platform 22-2 (Block 150). In some embodiments, the method further comprises performing a power system study of the inverter-based resource or plant 12 on the second software platform 22-2, with the inverter-based resource or plant 12 modeled with the custom model 36 in the second software platform 22-2 (Block 160).

In some embodiments, generating the training data 24R further comprises generating the training data 24R also from field measurements of instantaneous time-domain responses 24 of the inverter-based resource or plant 12 to one or more of the conditions.

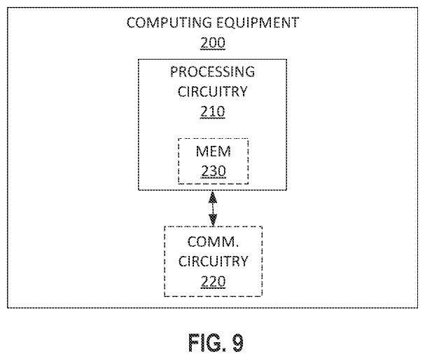

Embodiments herein also include corresponding apparatuses. Embodiments herein for instance include computing equipment 200 shown in FIG. 9. The computing equipment 200 is configured to perform any of the steps of any of the embodiments described above. In particular, the computing equipment 200 as shown includes processing circuitry 210 configured to perform any of the steps of any of the embodiments described above. In one such embodiment, the computing equipment further comprises memory 230, e.g., the memory 230 may contain instructions executable by the processing circuitry 210 whereby the computing equipment 200 is configured to perform any of the steps of any of the embodiments described above. In some embodiments, the computing equipment 200 also includes power supply circuitry (not shown) configured to supply power to the computing equipment 200. Alternatively or additionally, in some embodiments, the computing equipment 200 also comprises communication circuitry 220.

More particularly, the apparatuses described above may perform the methods herein and any other processing by implementing any functional means, modules, units, or circuitry. In one embodiment, for example, the apparatuses comprise respective circuits or circuitry configured to perform the steps shown in the method figures. The circuits or circuitry in this regard may comprise circuits dedicated to performing certain functional processing and/or one or more microprocessors in conjunction with memory. For instance, the circuitry may include one or more microprocessor or microcontrollers, as well as other digital hardware, which may include digital signal processors (DSPs), special-purpose digital logic, and the like. The processing circuitry may be configured to execute program code stored in memory, which may include one or several types of memory such as read-only memory (ROM), random-access memory, cache memory, flash memory devices, optical storage devices, etc. Program code stored in memory may include program instructions for carrying out one or more of the techniques described herein, in several embodiments. In embodiments that employ memory, the memory stores program code that, when executed by the one or more processors, carries out the techniques described herein.

Those skilled in the art will also appreciate that embodiments herein further include corresponding computer programs.

A computer program comprises instructions which, when executed on at least one processor of computing equipment 200, cause the computing equipment 200 to carry out any of the respective processing described above. A computer program in this regard may comprise one or more code modules corresponding to the means or units described above.

Embodiments further include a carrier containing such a computer program. This carrier may comprise one of an electronic signal, optical signal, radio signal, or computer readable storage medium.

In this regard, embodiments herein also include a computer program product stored on a non-transitory computer readable (storage or recording) medium and comprising instructions that, when executed by a processor of computing equipment 200, cause the computing equipment 200 to perform as described above.

Embodiments further include a computer program product comprising program code portions for performing the steps of any of the embodiments herein when the computer program product is executed by computing equipment 200. This computer program product may be stored on a computer readable recording medium.

In certain embodiments, some or all of the functionality described herein may be provided by processing circuitry executing instructions stored on in memory, which in certain embodiments may be a computer program product in the form of a non-transitory computer-readable storage medium. In alternative embodiments, some or all of the functionality may be provided by the processing circuitry without executing instructions stored on a separate or discrete device-readable storage medium, such as in a hard-wired manner. In any of those particular embodiments, whether executing instructions stored on a non-transitory computer-readable storage medium or not, the processing circuitry can be configured to perform the described functionality. The benefits provided by such functionality are not limited to the processing circuitry alone or to other components of the computing device, but are enjoyed by the computing device as a whole.

What is claimed is:

1. A method for exporting a black-box model of an inverter-based resource or plant from a first software platform for use by a second software platform, the method comprising:
simulating, using the first software platform, instantaneous time-domain responses of the inverter-based resource or plant to respective conditions defined by a script, according to the black-box model of the inverter-based resource or plant;
generating training data from the instantaneous time-domain responses and the respective conditions;
with the training data, training a machine learning model to model the inverter-based resource or plant, wherein the trained machine learning model is transparent as to its inner workings; and
generating software code that represents the trained machine learning model in terms of software code that is usable for defining a custom model of the inverter-based resource or plant in the second software platform.

2. The method of claim 1, wherein the black-box model is specific to the first software platform, and wherein the generated software code is not specific to the first software platform.

3. The method of claim 1, wherein the first software platform is a first non-real-time Electromagnetic Transient (EMT) simulation platform, and wherein the second software platform is a second non-real-time EMT simulation platform or a real-time EMT simulation platform.

4. The method of claim 1, wherein the machine learning model is a deep learning model.

5. The method of claim 1, wherein the machine learning model is a long short-term memory (LSTM) network.

6. The method of claim 1, wherein the software code is C or C++ code.

7. The method of claim 1, wherein the script is a Python script.

8. The method of claim 1, further comprising defining a custom model of the inverter-based resource or plant in the second software platform by importing the generated software code into the second software platform.

9. The method of claim 8, further comprising performing a power system study of the inverter-based resource or plant on the second software platform, with the inverter-based resource or plant modeled with the custom model in the second software platform.

10. The method of claim 1, wherein generating the training data further comprises generating the training data also from field measurements of instantaneous time-domain responses of the inverter-based resource or plant to one or more of the conditions.

11. A non-transitory computer-readable medium on which is stored instructions that, when executed by one or more processors of computing equipment, cause the computing equipment to export a black-box model of an inverter-based resource or plant from a first software platform for use by a second software platform, the instructions configured to cause the computing equipment to:
simulate, using the first software platform, instantaneous time-domain responses of the inverter-based resource or plant to respective conditions defined by a script, according to the black-box model of the inverter-based resource or plant;
generate training data from the instantaneous time-domain responses and the respective conditions;
with the training data, train a machine learning model to model the inverter-based resource or plant, wherein the trained machine learning model is transparent as to its inner workings; and
generate software code that represents the trained machine learning model in terms of software code that is usable for defining a custom model of the inverter-based resource or plant in the second software platform.

12. The non-transitory computer-readable medium of claim 11, wherein the black-box model is specific to the first software platform, and wherein the generated software code is not specific to the first software platform.

13. The non-transitory computer-readable medium of claim 11, wherein the first software platform is a first non-real-time Electromagnetic Transient (EMT) simulation platform, and wherein the second software platform is a second non-real-time EMT simulation platform or a real-time EMT software platform.

14. The non-transitory computer-readable medium of claim 11, wherein the machine learning model is a deep learning model.

15. The non-transitory computer-readable medium of claim 11, wherein the machine learning model is a long short-term memory (LSTM) network.

16. The non-transitory computer-readable medium of claim 11, wherein the software code is C or C++ code.

17. The non-transitory computer-readable medium of claim 11, wherein the script is a Python script.

18. The non-transitory computer-readable medium of claim 11, the instructions further configured to cause the computing equipment to define a custom model of the inverter-based resource or plant in the second software platform by importing the generated software code into the second software platform.

19. The non-transitory computer-readable medium of claim 18, the instructions further configured to cause the computing equipment to perform a power system study of the inverter-based resource or plant on the second software platform, with the inverter-based resource or plant modeled with the custom model in the second software platform.

20. The non-transitory computer-readable medium of claim 11, the instructions configured to cause the computing equipment to generate the training data also from field measurements of instantaneous time-domain responses of the inverter-based resource or plant to one or more of the conditions.

21. Computing equipment for exporting a black-box model of an inverter-based resource or plant from a first software platform for use by a second software platform, the computing equipment comprising processing circuitry configured to:
simulate, using the first software platform, instantaneous time-domain responses of the inverter-based resource or plant to respective conditions defined by a script, according to the black-box model of the inverter-based resource or plant;
generate training data from the instantaneous time-domain responses and the respective conditions;
with the training data, train a machine learning model to model the inverter-based resource or plant, wherein the trained machine learning model is transparent as to its inner workings; and
generate software code that represents the trained machine learning model in terms of software code that is usable for defining a custom model of the inverter-based resource or plant in the second software platform.
